(19) United States
(12) Patent Application Publication
(10) Pub. No.: US 2013/0078780 A1
(43) Pub. Date: Mar. 28, 2013

(54) SEMICONDUCTOR PROCESS

(71) Applicants: Chin-Fu Lin, Tainan City (TW); Chih-Chien Liu, Taipei City (TW); Teng-Chun Tsai, Tainan City (TW); Chin-Cheng Chien, Tainan City (TW); Chun-Yuan Wu, Yun-Lin County (TW)

(72) Inventors: Chin-Fu Lin, Tainan City (TW); Chih-Chien Liu, Taipei City (TW); Teng-Chun Tsai, Tainan City (TW); Chin-Cheng Chien, Tainan City (TW); Chun-Yuan Wu, Yun-Lin County (TW)

(21) Appl. No.: 13/241,188

(22) Filed: Sep. 22, 2011

(51) Int. Cl. H01L 21/336

(52) U.S. Cl. 438/303; 257/E21.409

(57) ABSTRACT

A semiconductor process includes the following steps. An interlayer is formed on a substrate. A first metallic oxide layer is formed on the interlayer. A reduction process is performed to reduce the first metallic oxide layer into a metal layer. A high temperature process is performed to transform the metal layer to a second metallic oxide layer.

### BACKGROUND OF THE INVENTION

1. Field of the Invention

The present invention relates generally to a semiconductor process, and more specifically to a semiconductor process that performs a reduction process and a high temperature process to reduce the thickness of a gate oxide layer.

2. Description of the Prior Art

Poly-silicon is conventionally used as a gate electrode in semiconductor devices, such as the metal-oxide-semiconductor (MOS). With the trend towards scaling down the size of semiconductor devices, the conventional poly-silicon gate faces problems such as inferior performance due to boron penetration and unavoidable depletion effect, which increases the equivalent thickness of the gate dielectric layer, reduces gate capacitance, and worsens a driving force of the devices. Therefore, work function metals are used to replace the conventional poly-silicon gate to be the control electrode.

Work function metals are suitable for being paired with a dielectric layer that has a high dielectric constant. Due to the difference in material characteristics and lattice constant between a dielectric layer with a high dielectric constant and a substrate (such as a silicon substrate), an interlayer is disposed between the dielectric layer with a high dielectric constant and the substrate for buffering. The thickness of the interlayer should be as thin as possible as the size of semiconductor components is minimized. The thickness of the interlayer can not be scaled down to 5˜6 A, however, because of process restrictions.

### SUMMARY OF THE INVENTION

The present invention therefore provides a semiconductor process that can reduce the thickness of the aforesaid interlayer.

The present invention provides a semiconductor process including the following steps. An interlayer is formed on a substrate. A first metallic oxide layer is formed on the interlayer. A reduction process is performed to reduce the surface of the first metallic oxide layer to a metal layer. A high temperature process is performed to transform the metal layer into a second metallic oxide layer.

The present invention provides a semiconductor process, which performs a reduction process and a high temperature process to reduce a metallic oxide layer to a metal layer, and then oxidize the metal layer into a metallic oxide layer. In one case, if the oxygen atoms used in the oxidation method are provided from the interlayer below, the interlayer can also be reduced while the metal layer is oxidized. Therefore, the effective oxide thickness of the interlayer can be reduced and the total effective oxide thickness of the metal gate can also be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 schematically depict a cross-sectional view of a semiconductor process according to one preferred embodiment of the present invention.

FIGS. 4-10 schematically depict a cross-sectional view of a MOS transistor process according to one preferred embodiment of the present invention.

### DETAILED DESCRIPTION

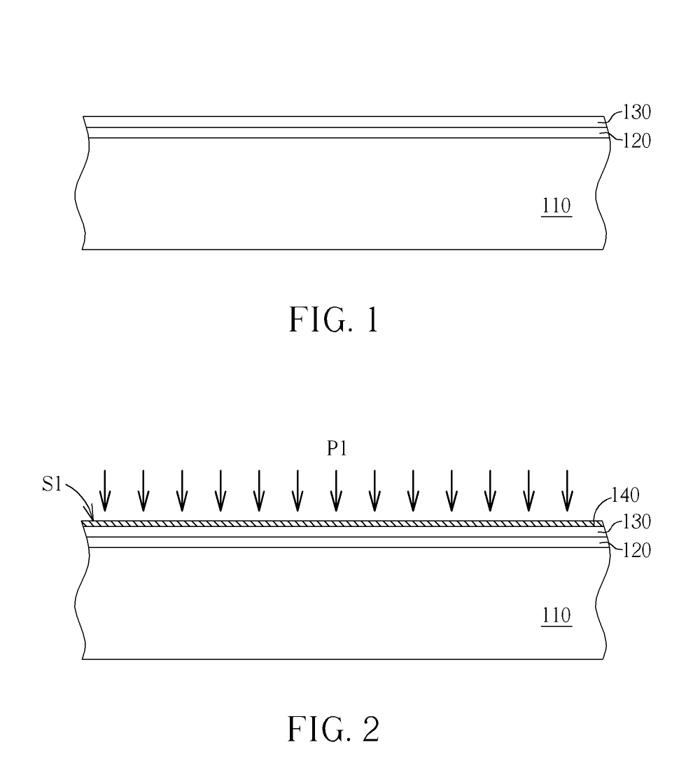

FIGS. 1-3 schematically depict a cross-sectional view of a semiconductor process according to one preferred embodiment of the present invention. As shown in FIG. 1, a substrate 110 is provided, wherein the substrate 110 includes a semiconductor substrate such as a silicon substrate, a silicon containing substrate or a silicon on insulator substrate. An interlayer 120 is formed on the substrate 110. In an embodiment, the interlayer 120 may be an oxide layer (SiO₂) used as a buffer layer. An ammonia containing or hydrogen peroxide containing cleaning process is selectively performed to make the surface of the interlayer 120 have OH-bonds. A first metallic oxide layer 130 is formed on the interlayer 120. The first metallic oxide layer 130 may be a dielectric layer having a high dielectric constant such as a hafnium oxide layer and the first metallic oxide layer 130 can be used as a gate dielectric layer.

As shown in FIG. 2, a reduction process P1 is performed to at least reduce the surface S1 of the first metallic oxide layer 130 to a metal layer 140. The reduction process P1 may include a chemical reduction process, which may be a hydrogen containing reduction process or a hydrogen plasma containing reduction process such as a remote hydrogen plasma reduction process, etc., but it is not limited thereto.

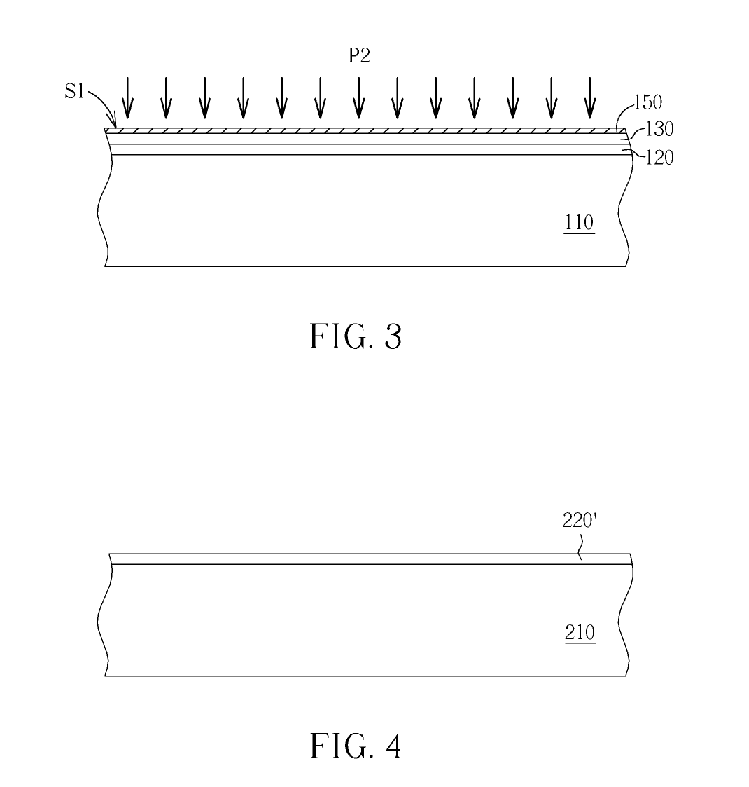

As shown in FIG. 3, a high temperature process P2 is performed to transform the metal layer 140 into a second metallic oxide layer 150. In one embodiment, the temperature of the high temperature process P2 is higher than 900° C. In one case, the high temperature process P2 may be a source/drain annealing process, but it is not limited thereto.

For example, the reduction process P1 can remove oxygen atoms in the first metallic oxide layer 130 (hafnium oxide layer, HfO₂) and transform the surface S1 of the first metallic oxide layer 130 to the metal layer 140 (hafnium metal layer), so the first metallic oxide layer 130 and the metal layer 140 have the same metal atom (hafnium atom). Then, the high temperature process P2 is performed to make the metal layer 140 oxidize to the second metallic oxide layer 150. As an example, the interlayer 120 is an oxide layer. The high temperature process P2 is a heating process, which can make the metal layer 140 react with oxygen atoms in the interlayer 120 and transform into a second metallic oxide layer 150 without importing oxygen. In other words, the high temperature process P2 also reduces a portion of the interlayer 120. As the second metallic oxide layer 150 is formed by oxidizing the metal layer 140, the second metallic oxide layer 150 and the first metallic oxide layer 130 have the same metal atom. In a preferred embodiment, the first metallic oxide layer 130 and the second metallic oxide layer 150 substantially have the same micro-structure feature.

Above all, the present invention provides a semiconductor process, which reduces the surface of the first metallic oxide layer into a metal layer, and then oxidizes the metal layer by absorbing the oxygen atoms of the interlayer below the first metallic oxide layer to the metal layer, to reduce a portion of the interlayer. Therefore, the semiconductor process of the present invention can reduce the effective oxide thickness (EOT) of the interlayer without increasing the thickness of the first metallic oxide layer. To sum up, the present invention can reduce the total effective oxide thickness (EOT) of the interlayer and the first metallic oxide layer (it means a gate dielectric layer as applied in a MOS transistor.), thereby improving the electrical performance of the semiconductor components.

An embodiment is provided in the following, which applies the semiconductor process of the present invention to a MOS transistor; especially, to a Gate-Last for High-K first process of a MOS transistor, but it is not limited thereto.

FIGS. 4-10 schematically depict a cross-sectional view of a MOS transistor process according to one preferred embodiment of the present invention. As shown in FIG. 4, a substrate 210 is provided, wherein the substrate 210 includes a semiconductor substrate such as a silicon substrate, a silicon-containing substrate or a silicon on insulator substrate. This embodiment uses a silicon substrate as an example. An interlayer 220′ is formed on the substrate 210. In this embodiment, the interlayer 220′ is a buffer layer, which may be an oxide layer formed by performing a thermal oxidation process on the surface of the substrate 210. An ammonia containing or hydrogen peroxide containing cleaning process is selectively performed to make the surface of the interlayer 220′ have OH-bonds.

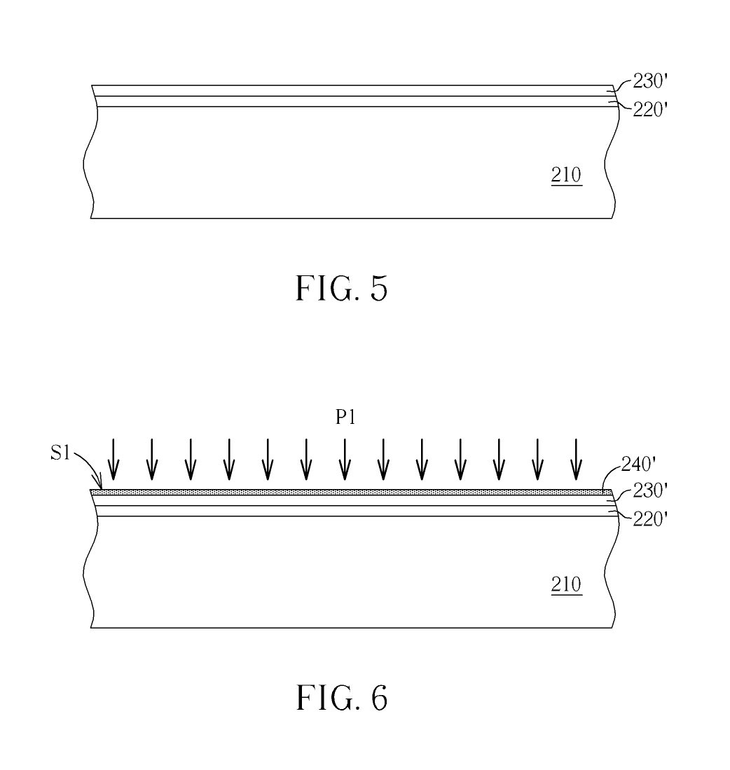

As shown in FIG. 5, a first metallic oxide layer 230′ is formed on the interlayer 220′. In this embodiment, the first metallic oxide layer 230′ is a gate dielectric layer, and more specifically, is a dielectric layer having a high dielectric constant. The material of the dielectric layer having a high dielectric constant may be the group selected from hafnium oxide layer (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalite (SrBi₂Ta₂O₉, SBT), lead zirconate titanate (PbZrₓTi₁₋ₓO₃, PZT) and barium strontium titanate (BaₓSr₁₋ₓTiO₃, BST).

As shown in FIG. 6, a reduction process P1 is performed to at least reduce the surface S1 of the first metallic oxide layer 230′ to a metal layer 240′. In one case, the thickness of the metal layer 240′ may be 2%˜50% of the thickness of the first metallic oxide layer 230′, preferably 10%˜30% of the thickness of the first metallic oxide layer 230′. The reduction process P1 may include a chemical reduction process, which may be a hydrogen containing reduction process or a hydrogen plasma containing reduction process such as a remote hydrogen plasma reduction process, but it is not limited thereto.

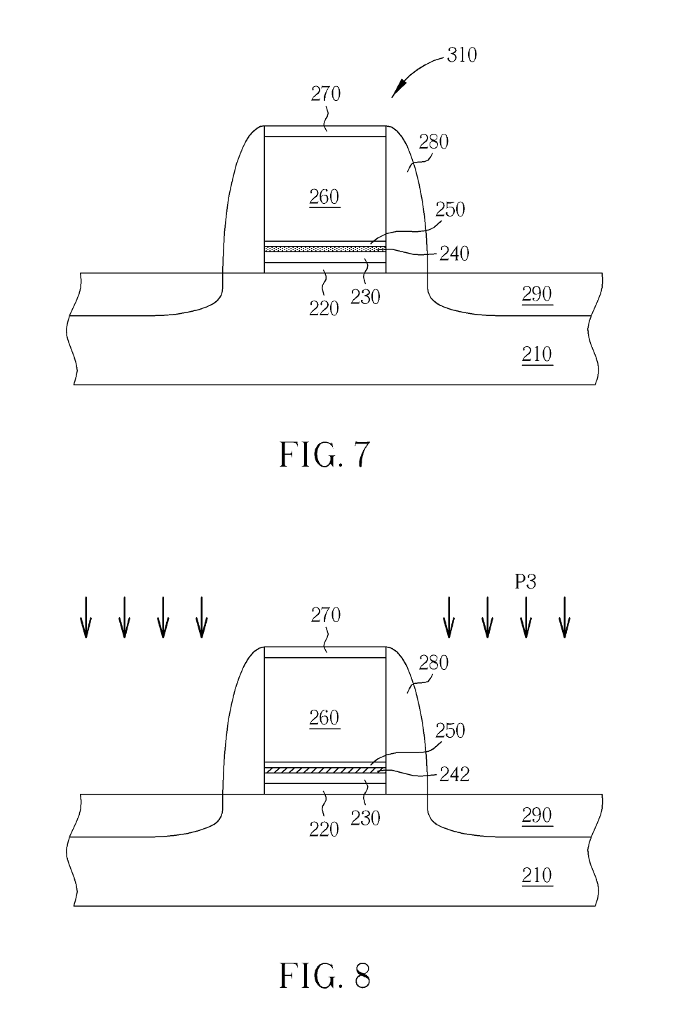

As shown in FIG. 7, a sacrificed gate 310 is formed, wherein the forming method of the sacrificed gate 310 may be: selectively forming a barrier layer (not shown) on the metal layer 240′; forming a sacrificed gate layer (not shown) on the barrier layer (or a metal layer 240′); forming a cap layer (not shown) on the sacrificed gate layer; patterning the cap layer, the sacrificed gate layer, the barrier layer, the metal layer 240′, the first metallic oxide layer 230′ and the interlayer 220′ to form an interlayer 220, a first metallic oxide layer 230, a metal layer 240, a barrier layer 250, a sacrificed gate layer 260 and a cap layer 270; and forming a spacer 280 beside the cap layer 270, the sacrificed gate layer 260, the barrier layer 250, the metal layer 240, the first metallic oxide layer 230 and the interlayer 220. Then, an ion implantation process is performed to form a source/drain region 290 in the substrate 210 beside the spacer 280.

As shown in FIG. 8, a source/drain annealing process P3 is performed to activate the source/drain region 290. In one embodiment, the processing temperature of the source/drain annealing process P3 is higher than 900° C. This means the metal layer 240 can transform into a second metallic oxide layer 242 by the temperature of the source/drain annealing process P3.

In this embodiment, due to the metal layer 240 being reduced by the first metallic oxide layer 230, the metal layer 240 should be a layer formed by removing oxygen atoms of the first metallic oxide layer 230. Thus, the metal layer 240 and the first metallic oxide layer 230 of this embodiment should have the same metal atom. Furthermore, the second metallic oxide layer 242 can be formed by absorbing oxygen atoms in the interlayer 220 to the metal layer 240 and then inducing the metal layer 240 to be oxidized into an oxide layer while the source/drain annealing process P3 is performed. Therefore, the second metallic oxide layer 242 and the first metallic oxide layer 230 have the same metal atom. In an embodiment, the second metallic oxide layer 242 and the first metallic oxide layer 230 substantially have the same microstructure. Due to oxygen atoms in the interlayer 220 being absorbed by the metal layer 240, a portion of the interlayer 220 can also be reduced. As a result, the present invention can reduce the effective oxide thickness (EOT) of the interlayer 220 without substantially affecting the thickness of the first metallic oxide layer 230. The semiconductor process of the present invention can therefore reduce the effective oxide thickness (EOT) of a gate such as a metal gate formed by a metallic oxide layer such as a dielectric layer having a high dielectric constant. As the present invention transforms the metal layer 240 into the second metallic oxide layer 242 while the source/drain annealing process P3 is performed for activating the source/drain region 290, the present invention does not need to further perform a high temperature process, thereby reducing processing costs.

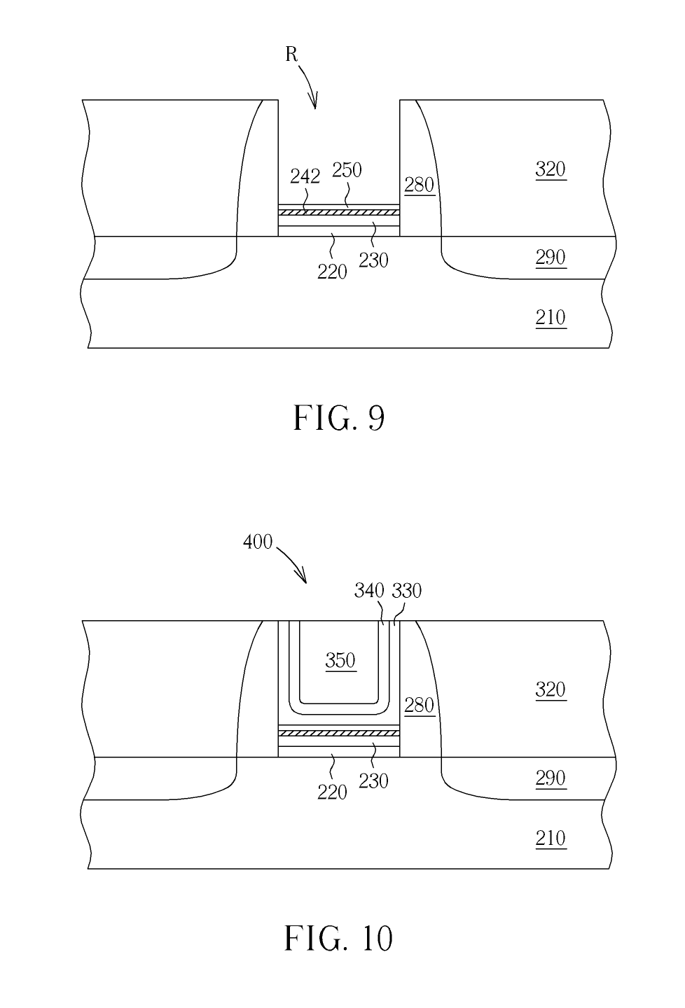

As shown in FIG. 9, an interdielectric layer 320 is formed to cover the sacrificed gate 310 and the substrate 210 and then the interdielectric layer 320 is planarized to expose the cap layer 270. The cap layer 270 and the sacrificed gate layer 260 are removed by using the barrier layer 250 as an etch stop layer to form a recess R.

As shown in FIG. 10, a metal gate layer 400 is formed to replace the sacrificed gate layer 260, wherein the metal gate layer 400 may include a work function metal layer 330, a barrier layer 340 and a main electrode layer 350. The forming method of the metal gate layer 400 is known in the art, and therefore is not described in detail here.

The present invention can also be applied to a Gate-Last for High-K last process. The source/drain annealing process is performed before the dielectric layer having a high dielectric constant is formed, so that a high temperature process should be further performed after the dielectric layer having a high dielectric constant is formed. Or, the present invention can be applied to a Gate-First process. Therefore, a metal gate is formed without the sacrificed gate 310 being formed. Additionally, the reduction process and the high temperature process of the present invention are not restricted to be performed one time only; both processes can be performed many times, and the performance timings can be different. The reduction process of the present invention at least reduces the surface of the first metallic oxide layer to a metal layer, but the reduction process of the present invention can also reduce the whole first metallic oxide layer, wherein modifications depend upon processing needs.

Above all, the semiconductor process of the present invention performs a reduction process and a high temperature process to reduce a metallic oxide layer into a metal layer, and then oxidize the metal layer into a metallic oxide layer. In one case, if the oxygen atoms used in the oxidation method are provided from the interlayer below, the interlayer can also be reduced while the metal layer is oxidized. The effective oxide thickness of the interlayer can thereby be reduced and the total effective oxide thickness of the metal gate can also be reduced.

The chemical reduction process applied in the present invention can control the thickness of the metal layer easier and costs less as compared to a physical vapor deposition process, which directly deposits a metal layer on the first metallic oxide layer. If a metal layer is deposited on the first metallic oxide layer, then a thermal treatment is performed to make the oxygen atoms in the interlayer attracted to the metal layer, and the metal layer therefore transforms to the metallic oxide layer, the equivalent oxide thickness of the interlayer reduces, but the thickness of the metallic oxide layer of the dielectric layer having a high dielectric constant increases. So, this method is not good for reducing the total equivalent oxide thickness of a metal gate.

Those skilled in the art will readily observe that numerous modifications and alterations of the device and method may be made while retaining the teachings of the invention.

What is claimed is:

1. A semiconductor process, comprising:
forming an interlayer on a substrate;
forming a first metallic oxide layer on the interlayer;
performing a reduction process to reduce the surface of the first metallic oxide layer to a metal layer; and
performing a high temperature process to transform the metal layer into a second metallic oxide layer.

2. The semiconductor process according to claim 1, wherein after the first metallic oxide layer is formed, the reduction process is performed.

3. The semiconductor process according to claim 1, further comprising:
forming a sacrificed gate or a metal gate.

4. The semiconductor process according to claim 1, wherein the interlayer comprises an oxide layer.

5. The semiconductor process according to claim 4, wherein the high temperature process is used for making the metal layer react with oxygen atoms in the interlayer, to oxidize the metal layer to the second metallic oxide layer.

6. The semiconductor process according to claim 5, wherein the high temperature process reduces a portion of the interlayer at the same time.

7. The semiconductor process according to claim 1, wherein the first metallic oxide layer comprises a gate dielectric layer.

8. The semiconductor process according to claim 7, wherein the first metallic oxide layer comprises a dielectric layer having a high dielectric constant.

9. The semiconductor process according to claim 8, wherein the first metallic oxide layer comprises a hafnium oxide layer.

10. The semiconductor process according to claim 1, wherein the reduction process comprises a hydrogen containing reduction process or a hydrogen plasma containing reduction process.

11. The semiconductor process according to claim 1, wherein the temperature of the high temperature process is higher than 900° C.

12. The semiconductor process according to claim 5, wherein the high temperature process comprises a source/drain annealing process.

13. The semiconductor process according to claim 12, further comprising:
after performing the reduction process, forming a sacrificed gate layer on the first metallic oxide layer;
patterning the sacrificed gate layer and the first metallic oxide layer;
forming a spacer beside the sacrificed gate layer and the first metallic oxide layer; and
performing an ion implantation process to form a source/drain region in the substrate beside the spacer.

14. The semiconductor process according to claim 13, further comprising:
forming a barrier layer between the sacrificed gate layer and the first metallic oxide layer, wherein the barrier layer is also patterned as the first metallic oxide layer and the sacrificed gate layer are patterned.

15. The semiconductor process according to claim 13, further comprising:
replacing the sacrificed gate layer as a metal gate layer.

16. The semiconductor process according to claim 1, further comprising:
after forming the interlayer on the substrate, performing an ammonia containing or hydrogen peroxide containing cleaning process to make the surface of the interlayer have OH-bonds.
